(19) United States
(12) Patent Application Publication
(10) Pub. No.: US 2025/0180619 A1
(43) Pub. Date: Jun. 5, 2025

(54) DETECTION METHOD, SYSTEM, AND STORAGE MEDIUM FOR FLUXGATE SENSOR NOISE

(71) Applicant: Institute of Geology an Geophysics Chinese Academy of Sciences, Beijing (CN)

(72) Inventors: Zhi LI, Beijing (CN); Yasong GE, Beijing (CN); Lin ZHAO, Beijing (CN); Shuquan SUN, Beijing (CN); Xiao FENG, Beijing (CN); Ying ZHANG, Beijing (CN)

(73) Assignee: Institute of Geology an Geophysics Chinese Academy of Sciences, Beijing (CN)

(21) Appl. No.: 18/434,837

(22) Filed: Feb. 7, 2024

(30) Foreign Application Priority Data
Dec. 4, 2023 (CN) 202311648307.8

(51) Int. Cl. G01R 29/26; G01R 33/04; H05K 9/00

(52) U.S. Cl. CPC G01R 29/26; H05K 9/0071; G01R 33/04

(57) ABSTRACT

A method, a system, and a storage medium for detecting noise of a fluxgate sensor are disclosed. Acquiring sensitivity of the fluxgate sensor; acquiring open-loop sensitivity of the probe of the fluxgate sensor; placing the probe in a magnetic shielding module to obtain the total noise of the fluxgate sensor; setting a probe replacing circuit to replace the probe, and placing it in a magnetic shielding module to obtain external noise introduced by parts outside the probe; acquiring the open-loop noise of the probe based on the total noise of the fluxgate sensor and the external noise; calculating the closed-loop noise of the probe by multiplying the open-loop noise by the ratio of the sensitivity of the fluxgate sensor to the open-loop sensitivity of the probe; and acquiring the actual noise of the fluxgate sensor based on the closed-loop noise of the probe and the external noise.

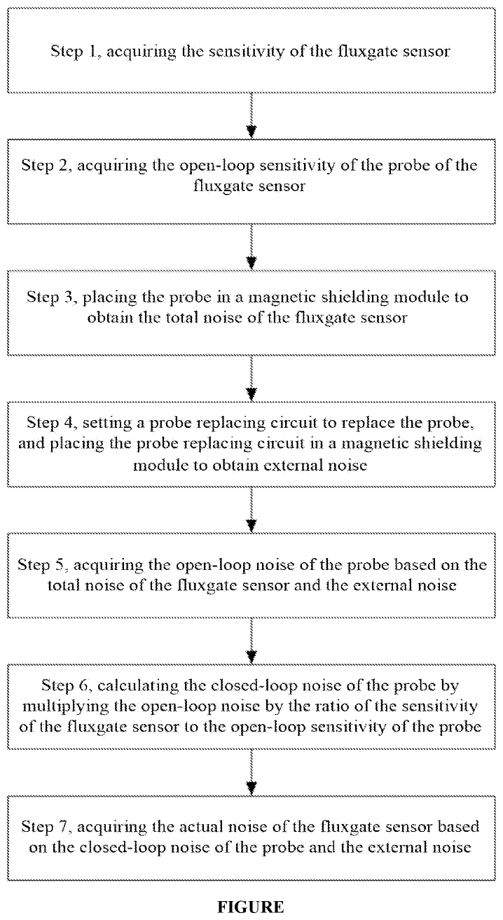

### CROSS-REFERENCE TO THE RELATED APPLICATIONS

This application is based upon and claims priority to Chinese Patent Application No. 202311648307.8, filed on Dec. 4, 2023, the entire contents of which are incorporated herein by reference.

### TECHNICAL FIELD

The present disclosure relates to the field of noise detection technology for fluxgate sensor, in particular to a method, a system, and a storage medium for detecting noise of fluxgate sensor.

### BACKGROUND

A fluxgate sensor is a kind of sensor that measures the weak magnetic field by utilizing the nonlinear relationship between the magnetic induction intensity and the magnetic field intensity of the high-permeability magnetic core in the measured magnetic field under the saturation excitation of the alternating magnetic field. As a traditional weak magnetic field detection device, the fluxgate sensor has its unique advantages and cannot be replaced by other magnetic field sensors. In recent years, its application potential has been found in new fields, such as medical treatment, geophysical exploration, space physics, underwater magnetic anomaly detection and so on.

Noise level is one of the key technical parameters of a fluxgate sensor, and the optimization of noise level is also a key step in the development process of a fluxgate sensor. Because the existing noise detection methods cannot evaluate the noise contribution of the probe and other external noise separately, sensor developers cannot carry out noise optimization design based on the probe and external noise separately, which leads to the poor pertinence and effect of the current noise optimization design. In addition, in the existing noise detection method for the fluxgate sensor, when detecting the noise of a sensor probe or external noise, a control group is not set, and the influence of other external factors such as environment and the like on the noise measurement of the probe is not considered, so that the technical defect of low accuracy of noise detection is easily caused.

Based on this, it is an urgent problem for those skilled in the art to solve how to provide a method with higher noise detection accuracy and capable of detecting the probe and the external noise separately.

### SUMMARY

In view of this, the present disclosure provides a method, a system, and a storage medium for detecting noise of a fluxgate sensor.

In order to achieve the above effects, the present disclosure adopts the following technical solutions.

A method for detecting noise of a fluxgate sensor includes:
Step 1, acquiring the sensitivity of the fluxgate sensor;
Step 2, acquiring the open-loop sensitivity of the probe of the fluxgate sensor;
Step 3, placing the probe in a magnetic shielding module to obtain the total noise of the fluxgate sensor;
Step 4, setting a probe replacing circuit to replace the probe, and placing the probe replacing circuit in a magnetic shielding module to obtain external noise introduced by parts outside the probe;
Step 5, acquiring the open-loop noise of the probe based on the total noise of the fluxgate sensor and the external noise;
Step 6, calculating the closed-loop noise of the probe by multiplying the open-loop noise by the ratio of the sensitivity of the fluxgate sensor to the open-loop sensitivity of the probe; and
Step 7, acquiring the actual noise of the fluxgate sensor based on the closed-loop noise of the probe and the external noise.

Optionally, in the Step 1, a dynamic signal analyzer is configured to acquire the sensitivity of the fluxgate sensor.

Optionally, in the Step 2, the method for acquiring the open-loop sensitivity of the probe includes:
exciting the probe with an alternating current source;
applying a direct-current (DC) field having a predetermined field strength to the probe, demodulating an output voltage of the probe by utilizing a lock-in amplifier, and obtaining an effective value of the demodulated output voltage at the predetermined field strength; and
calculating the open-loop sensitivity of the probe based on the effective value of the demodulated output voltage and the predetermined field strength.

Optionally, the magnetic shielding module includes an active magnetic shielding equipment, a magnetic shielding chamber and a magnetic shielding cylinder; a three-axis active magnetic shielding coil in the active magnetic shielding equipment is surrounded outside the magnetic shielding chamber, the magnetic shielding cylinder is nested in the magnetic shielding chamber, the probe is placed in the magnetic shielding module, and the noise spectrum of the output signal of the probe is measured.

Optionally, in the step 4, the probe replacing circuit includes an adder and a multiplier, and the output end of the adder is connected to the input end of the multiplier; the adder is configured to make a difference between the magnetic field to be measured and the feedback magnetic field to obtain a magnetic field difference value; the multiplier is configured to multiply the magnetic field difference value with the excitation current to obtain a probe simulation output. Both the adder and the multiplier are constructed based on an operational amplifier.

The present disclosure further provides a system for detecting noise of a fluxgate sensor, including:
a sensor sensitivity acquisition module, which is configured to acquire the sensitivity of the fluxgate sensor;
a probe open-loop sensitivity acquisition module, which is configured to acquire the open-loop sensitivity of the probe of the fluxgate sensor;
a total noise acquisition module, which is configured to place the probe in a magnetic shielding module to obtain the total noise of the fluxgate sensor;
an external noise measurement module, which is configured to set a probe replacing circuit to replace the probe, and placing the probe replacing circuit in a magnetic shielding module to obtain external noise introduced by parts outside the probe;
a probe open-loop noise acquisition module, which is configured to acquire the open-loop noise of the probe based on the total noise of the fluxgate sensor and the external noise;
a probe closed-loop noise acquisition module, which is configured to calculate the closed-loop noise of the probe by multiplying the open-loop noise by the ratio of the sensitivity of the fluxgate sensor to the open-loop sensitivity of the probe; and
a probe actual noise acquisition module, which is configured to acquire the actual noise of the fluxgate sensor based on the closed-loop noise of the probe and the external noise.

The present disclosure further provides a computer readable storage medium on which a computer program is stored, which is loaded by a processor to perform the steps of the method for detecting noise of the fluxgate sensor according to any one of the above.

According to the above technical solutions, the present disclosure provides a method, a system, and a storage medium for detecting noise of a fluxgate sensor. Compared with the prior art, the present disclosure has the following beneficial effects:

According to the disclosure, the probe replacing circuit is arranged to replace the probe so as to obtain the external noise outside the probe, and the closed-loop noise of the probe is calculated based on the open-loop noise of the probe, the sensitivity of the fluxgate sensor and the open-loop sensitivity of the probe. The disclosure can respectively perform noise detection on the probe and the external noise, and the accuracy of noise detection is higher.

### BRIEF DESCRIPTION OF THE DRAWINGS

In order to more clearly illustrate the embodiments of the present disclosure or technical solutions in the related art, the accompanying drawings used in the embodiments or the related art will now be described briefly. It is obvious that the drawings in the following description are only the embodiment of the disclosure, and that those skilled in the art can obtain other drawings from these drawings without any creative efforts.

The FIGURE is a schematic diagram of the method steps of the present disclosure.

### DETAILED DESCRIPTION OF THE EMBODIMENTS

In the following, the technical solutions in the embodiments of the present disclosure will be clearly and completely described with reference to the drawings in the embodiments of the present disclosure. Obviously, the described embodiments are only a part of the embodiments of the present disclosure, but not all the embodiments thereof. Based on the embodiments of the present disclosure, all other embodiments obtained by those skilled in the art without any creative efforts shall fall within the scope of the present disclosure.

The present embodiment discloses a method for detecting noise of a fluxgate sensor, as shown in the FIGURE, including the following steps.

Step 1, acquiring the sensitivity of the fluxgate sensor.

When the sensitivity of the fluxgate sensor is measured, the alternating current source, the alternating and direct current shunt and the alternating magnetic field coil are connected in series, the dynamic signal analyzer is connected with the alternating and direct current shunt, and the other end of the dynamic signal analyzer is connected with the fluxgate sensor, so that the output voltage of the alternating current shunt and the output voltage of the fluxgate sensor are obtained, and finally, the sensitivity of the fluxgate sensor is obtained.

The method for calculating the sensitivity of the fluxgate sensor is as follows.

$${K}_{w} = {K}_{Bf} \frac{{U}_{j}}{{R}_{f} {U}_{O}}$$

where,
K_{Bf}—coil constant of alternating field coil, T/A
Uᵢ—output voltage of alternating and direct current shunt measured by dynamic signal analyzer, V;
Uₒ—output voltage of the fluxgate sensor measured by dynamic signal analyzer, V;
R_{f}—resistance of alternating and direct current shunt at calibrated frequency point, Ω.

Step 2, acquiring the open-loop sensitivity of the probe of the fluxgate sensor.

Exciting the probe with an alternating current source.

Applying a DC field having a predetermined field strength to the probe, demodulating an output voltage of the probe by utilizing a lock-in amplifier, and obtaining an effective value of the demodulated output voltage at the predetermined field strength. and

Calculating the open-loop sensitivity of the probe based on the effective value of the demodulated output voltage and the predetermined field strength.

$${A}_{o} = U / H$$

where, Aₒ is the open-loop sensitivity of the probe, U is the effective value of the demodulated output voltage, and H is the predetermined field strength.

Step 3, placing the probe in a magnetic shielding module to obtain the total noise of the fluxgate sensor.

The magnetic shielding module includes an active magnetic shielding equipment, a magnetic shielding chamber and a magnetic shielding cylinder; a three-axis active magnetic shielding coil in the active magnetic shielding equipment is surrounded outside the magnetic shielding chamber, the magnetic shielding cylinder is nested in the magnetic shielding chamber, the probe is placed in the magnetic shielding module, and the noise spectrum of the output signal of the probe is measured.

Step 4, setting a probe replacing circuit to replace the probe, and placing the probe replacing circuit in a magnetic shielding module to obtain external noise introduced by parts outside the probe.

The probe replacing circuit includes an adder and a multiplier, and the output end of the adder is connected to the input end of the multiplier; the adder is configured to make a difference between the magnetic field to be measured and the feedback magnetic field to obtain a magnetic field difference value; the multiplier is configured to multiply the magnetic field difference value with the excitation current to obtain a probe simulation output. Both the adder and the multiplier are constructed based on an operational amplifier

Step 5, acquiring the open-loop noise of the probe based on the total noise of the fluxgate sensor and the external noise.

Step 6, calculating the closed-loop noise of the probe by multiplying the open-loop noise by the ratio of the sensitivity of the fluxgate sensor to the open-loop sensitivity of the probe; and

Step 7, acquiring the actual noise of the fluxgate sensor based on the closed-loop noise of the probe and the external noise.

Another embodiment of the present disclosure also provides a system for detecting noise of a fluxgate sensor, including:
a sensor sensitivity acquisition module, which is configured to acquire the sensitivity of the fluxgate sensor;
a probe open-loop sensitivity acquisition module, which is configured to acquire the open-loop sensitivity of the probe of the fluxgate sensor;
a total noise acquisition module, which is configured to place the probe in a magnetic shielding module to obtain the total noise of the fluxgate sensor;
an external noise measurement module, which is configured to set a probe replacing circuit to replace the probe, and placing the probe replacing circuit in a magnetic shielding module to obtain external noise introduced by parts outside the probe;
a probe open-loop noise acquisition module, which is configured to acquire the open-loop noise of the probe based on the total noise of the fluxgate sensor and the external noise;
a probe closed-loop noise acquisition module, which is configured to calculate the closed-loop noise of the probe by multiplying the open-loop noise by the ratio of the sensitivity of the fluxgate sensor to the open-loop sensitivity of the probe; and
a probe actual noise acquisition module, which is configured to acquire the actual noise of the fluxgate sensor based on the closed-loop noise of the probe and the external noise.

For the system disclosed in the embodiment, since it corresponds to the method disclosed in the embodiment, the description is relatively simple, and the correlation is described with reference to the method part.

Another embodiment of the present disclosure also provides a computer readable storage medium on which a computer program is stored, which is loaded by a processor to perform the steps of the method for detecting noise of the fluxgate sensor according to any one of the above.

Various embodiments of the present specification are described in a progressive manner, and each embodiment focuses on the description that is different from the other embodiments, and the same or similar parts between the various embodiments are referred to with each other.

The above description of the disclosed embodiments enables those skilled in the art to implement or use the present disclosure. Various amendments to the embodiments will be apparent to those skilled in the art. The general principles defined herein may be implemented in other embodiments without departing from the spirit or scope of the disclosure. Therefore, the present disclosure will not be limited to the embodiments shown herein but is to be accorded the widest scope consistent with the principles and novel features disclosed herein.

1. A method for detecting noise of a fluxgate sensor, comprising:
step 1, acquiring sensitivity of the fluxgate sensor;
step 2, acquiring open-loop sensitivity of a probe of the fluxgate sensor;
step 3, placing the probe in a magnetic shielding module and then obtaining a total noise of the fluxgate sensor;
step 4, setting a probe replacing circuit and replacing the probe with the probe replacing circuit, and placing the probe replacing circuit in the magnetic shielding module and then-obtaining an external noise introduced by parts outside the probe;
step 5, acquiring an open-loop noise of the probe based on the total noise of the fluxgate sensor and the external noise;
step 6, calculating a closed-loop noise of the probe by multiplying the open-loop noise by a ratio of the sensitivity of the fluxgate sensor to the open-loop sensitivity of the probe; and
step 7, acquiring an actual noise of the fluxgate sensor based on both the closed-loop noise of the probe and the external noise.

2. The method for detecting the noise of the fluxgate sensor according to claim 1, wherein in the step 1, a dynamic signal analyzer is configured to acquire the sensitivity of the fluxgate sensor.

3. The method for detecting the noise of the fluxgate sensor according to claim 1, wherein in the step 2, a method for acquiring the open-loop sensitivity of the probe comprises:
exciting the probe with an alternating current source;
applying a direct-current (DC) field having a predetermined field strength to the probe, demodulating an output voltage of the probe by utilizing a lock-in amplifier and then obtaining a demodulated output voltage, and obtaining an effective value of the demodulated output voltage at the predetermined field strength; and
calculating the open-loop sensitivity of the probe based on the effective value of the demodulated output voltage and the predetermined field strength.

4. The method for detecting the noise of the fluxgate sensor according to claim 1, wherein the magnetic shielding module comprises an active magnetic shielding equipment, a magnetic shielding chamber and a magnetic shielding cylinder; a three-axis active magnetic shielding coil in the active magnetic shielding equipment is surrounded outside the magnetic shielding chamber, the magnetic shielding cylinder is nested in the magnetic shielding chamber, the probe is placed in the magnetic shielding module, and a noise spectrum of an output signal of the probe is measured.

5. The method for detecting the noise of the fluxgate sensor according to claim 1, wherein in the step 4, the probe replacing circuit comprises an adder and a multiplier, and an output end of the adder is connected to an input end of the multiplier; the adder is configured to make a difference between a magnetic field to be measured and a feedback magnetic field to obtain a magnetic field difference value; the multiplier is configured to multiply the magnetic field difference value with an excitation current to obtain a probe simulation output; both the adder and the multiplier are constructed based on an operational amplifier.

6. (canceled)

7. A non-transitory computer-readable storage medium, wherein a computer program is stored on the computer-readable storage medium, the computer program is loaded by a processor to perform the steps of the method for detecting the noise of the fluxgate sensor according to claim 1.

8. The non-transitory computer-readable storage medium according to claim 7, wherein in the step 1 of the method for detecting the noise of the fluxgate sensor, a dynamic signal analyzer is configured to acquire the sensitivity of the fluxgate sensor.

9. The non-transitory computer-readable storage medium according to claim 7, wherein in the step 2 of the method for detecting the noise of the fluxgate sensor, a method for acquiring the open-loop sensitivity of the probe comprises:
exciting the probe with an alternating current source;
applying a direct-current (DC) field having a predetermined field strength to the probe, demodulating an output voltage of the probe by utilizing a lock-in amplifier and then obtaining a demodulated output voltage, and obtaining an effective value of the demodulated output voltage at the predetermined field strength; and
calculating the open-loop sensitivity of the probe based on the effective value of the demodulated output voltage and the predetermined field strength.

10. The non-transitory computer-readable storage medium according to claim 7, wherein in the method for detecting the noise of the fluxgate sensor, the magnetic shielding module comprises an active magnetic shielding equipment, a magnetic shielding chamber and a magnetic shielding cylinder; a three-axis active magnetic shielding coil in the active magnetic shielding equipment is surrounded outside the magnetic shielding chamber, the magnetic shielding cylinder is nested in the magnetic shielding chamber, the probe is placed in the magnetic shielding module, and a noise spectrum of an output signal of the probe is measured.

11. The non-transitory computer-readable storage medium according to claim 7, wherein in the step 4 of the method for detecting the noise of the fluxgate sensor, the probe replacing circuit comprises an adder and a multiplier, and an output end of the adder is connected to an input end of the multiplier; the adder is configured to make a difference between a magnetic field to be measured and a feedback magnetic field to obtain a magnetic field difference value; the multiplier is configured to multiply the magnetic field difference value with an excitation current to obtain a probe simulation output; both the adder and the multiplier are constructed based on an operational amplifier.
